(19) United States
(12) Patent Application Publication
(10) Pub. No.: US 2013/0285175 A1
(43) Pub. Date: Oct. 31, 2013

(54) MICROMECHANICAL COMPONENT AND METHOD FOR MANUFACTURING A MICROMECHANICAL COMPONENT

(71) Applicants: Julian Gonska, Reutlingen (DE); Jens Frey, Filderstadt (DE); Herlbert Weber, Nuertingen (DE); Timo Schary, Bremen (DE); Thomas Mayer, Reutlingen (DE)

(72) Inventors: Julian Gonska, Reutlingen (DE); Jens Frey, Filderstadt (DE); Herlbert Weber, Nuertingen (DE); Timo Schary, Bremen (DE); Thomas Mayer, Reutlingen (DE)

(73) Assignee: Robert Bosch GmbH, Stuttgart (DE)

(21) Appl. No.: 13/869,756

(22) Filed: Apr. 24, 2013

(30) Foreign Application Priority Data
Apr. 25, 2012 (DE) 10 2012 206 869.4

(51) Int. Cl. B81B 7/00; B81C 1/00

(52) U.S. Cl. CPC B81B 7/007; B81C 1/00301
USPC 257/417; 438/51

(57) ABSTRACT

A micromechanical component, in particular a micromechanical sensor having a carrier substrate and having a cap substrate, and a manufacturing method are provided. The carrier substrate and the cap substrate are joined together with the aid of a eutectic bond connection or by a metallic solder connection or a glass solder connection (e.g., glass frit), in an edge area of the carrier substrate and the cap substrate. The connection of the carrier substrate and the cap substrate is established with the aid of connecting areas, and a stop trench or a stop protrusion or both a stop trench and a stop protrusion are situated within the edge areas in the bordering areas.

### FIELD OF THE INVENTION

The present invention is directed to a micromechanical component.

### BACKGROUND INFORMATION

An example of a micromechanical component is described in German Published Patent Application No. 10 2007 044 808, which describes a micromechanical component having a first wafer and a second wafer, the first wafer having at least one structural element and the second wafer having at least one mating structural element, the first and/or second wafer having a function area surrounded by a density area.

In eutectic bonding, in general two materials which have a lowest melting point, the so-called eutectic point, in their phase diagrams are brought into contact. At the proper temperature and with the proper mixing ratio, the two materials melt to foam a eutectic. The material melts below the melting point of the corresponding bond materials.

Since the two materials come into contact for eutectic bonding, the wafers on which the individual layers are situated, i.e., a carrier substrate and a cap substrate, are compressed under pressure and acted upon by temperature. The individual layers are usually structured in advance to join only defined areas on a wafer, namely edge areas, which typically surround structured areas in the interior of the wafer or the carrier or cap substrate. At the moment when the eutectic point and thus the liquid phase are reached during heating, local liquefaction of the eutectic may occur, possibly even spreading uncontrollably outside of the edge area of the carrier substrate or of the cap substrate. If the liquid phase, i.e., the eutectic, penetrates into the structured area of the carrier substrate or the cap substrate, which may result in local bonding of sensor structures which are actually mobile, for example, mobile masses of acceleration sensors or yaw rate sensors, such a micromechanical component will no longer be usable subsequently, so the reject rate and thus manufacturing costs are increased.

### SUMMARY

The micromechanical component according to the present invention and the method according to the present invention for manufacturing a micromechanical component have the advantage in comparison with the related art that liquefaction of eutectic (or solder material) into regions of the carrier and/or cap substrate to be protected, in particular the structured area of the carrier and/or cap substrate—for example, the liquefaction of eutectic into sensor cores, such as acceleration sensors or yaw rate sensors, for example—is prevented by suitable stop structures. This is accomplished according to the present invention by the fact that a stop trench is provided in the first bordering area or in the second bordering area. Such a stop trench may also be provided in the first bordering area (of the carrier substrate) and in the second bordering area (of the cap substrate). As an alternative to providing one or multiple stop trenches, it may also be provided according to the present invention that a stop protrusion, i.e., a so-called spacer structure, for example, is situated in the first or second bordering area. As an alternative to this, it is also provided according to the present invention that a stop protrusion is provided in the first bordering area and another stop protrusion is provided in the second bordering area. Furthermore, it is also provided according to the present invention that both a stop trench and a stop protrusion are provided in the first or second bordering areas. Either the stop protrusion is provided in the first bordering area and the stop trench is provided in the second bordering area or vice-versa, or both the stop trench and the stop protrusion are provided in the first bordering area or in the second bordering area or in both the first bordering area and the second bordering area. It is advantageous in this way and easily possible to effectively prevent the penetration of eutectic, or the liquid phase in particular, into the structured area of the carrier substrate and/or the cap substrate, for example, in acceleration sensors and yaw rate sensors or micromirrors. Furthermore, when using stop protrusions or so-called spacer structures, it is also advantageously possible to homogenize the pinch height of the eutectic, i.e., the connecting layer(s) in the first connecting area of the carrier substrate and in the second connecting area of the cap substrate or between the first and second connecting areas, namely to make the entire connecting area of a single micromechanical element more uniform as well as making the manufacturing process of joining the carrier substrate and the cap substrate more reproducible over many micromechanical components and to do so with less scattering of the pinch height.

According to the present invention, the stop protrusion made of a thermal oxide material in particular is provided. It is advantageously preferably provided according to the present invention that the stop protrusion in particular is provided as a material applied to the material of the carrier substrate and/or to the material of the cap substrate or a material formed in the surface area of the carrier or cap substrate, in particular in the form of a structured layer, in particular made of an oxide material, preferably a thermal oxide material. This is advantageous in particular because—in particular in contrast with a structuring of the stop protrusion, in such a way that, out of the material of the carrier substrate and/or out of the material of the cap substrate, a selective etching of the material of the carrier substrate and/or of the cap substrate, typically with a comparatively poor uniformity of etching (uniformity of etching, i.e., etching uniformity) in the range of approximately ±5% accuracy over the entire area of a wafer is carried out—the deposition or formation of a layer of an oxide material (in particular silicon oxide and in particular thermal (silicon) oxide material) having a comparatively good uniformity of the layer thickness (uniformity) over the entire area of a wafer is possible, for example, with a layer thickness uniformity in the range of ±1% of the layer thickness of the deposited oxide layer (for example, after the oxide layer is formed, it is then etched (in particular in BOE), which is possible selectively to yield silicon), the layer thickness of the thermal oxide layer being on the order of magnitude of 0.5 micrometers to 2.5 micrometers, for example.

It is true in principle that for the design of the spacer thickness, the connecting materials in the connecting areas may be reliably brought into contact everywhere, and the volume resulting from the spacer thickness and the distance of the spacers from the connecting area is reliably able to receive the eutectic as it is liquefied.

The carrier substrate and/or the cap substrate preferably include(s) a semiconductor material, in particular silicon, which is structured accordingly to form the sensor structure, in particular a mobile mass or coupling springs. The structuring preferably takes place as part of lithography process steps and/or etching process steps and/or deposition process steps.

According to a preferred specific embodiment, it is provided that the first bordering area is situated between the first connecting area and the first structured area, and the second bordering area is situated between the second connecting area and the second structured area. According to the present invention, it is advantageously possible in this way to effectively prevent the penetration of the liquid phase of the eutectic into the structured area of both the carrier substrate and the cap substrate during joining of the carrier substrate and the cap substrate because the first bordering area for the carrier substrate and the second bordering area for the cap substrate represent a limit for the material of the liquid phase of the eutectic situated in the first and second connecting areas and it is prevented in this way from penetrating into the structured area of the carrier substrate or of the cap substrate.

Furthermore, it is preferred according to the present invention that the first edge area has a third bordering area in addition to the first bordering area and that the second edge area has a fourth bordering area in addition to the second bordering area, the first connecting area being situated between the first and third bordering areas (of the carrier substrate) and the second connecting area being situated between the second and fourth bordering areas (of the cap substrate). In this way according to the present invention, it is advantageously possible in a particular manner to limit the materials for the manufacture of the eutectic bond, in particular during their liquid phase during joining of the carrier substrate and the cap substrate, to the area of the first and second connecting areas of the carrier and cap substrates and thus to prevent penetration into the first and second structured areas of the carrier or cap substrate as well as to prevent the liquid phase of the eutectic from escaping to the outside out of the area of the first and second connecting areas.

Furthermore, it is preferred according to the present invention that the first edge area completely surrounds the first structured area on the first connecting side and the second edge area completely surrounds the second structured area on the second connecting side. It is advantageously possible in this way according to the present invention that a complete sealing of the atmosphere in the structured area is enabled, and that in particular the development of a high pressure or a low pressure or the establishment of an atmosphere in the structured area between the carrier substrate and the cap substrate is implementable.

Furthermore, it is also preferred according to the present invention that the eutectic bond connection comes about through a first bond partner and a second bond partner, the first bond partner being provided in the first connecting area and the second bond partner being provided in the second connecting area. The eutectic connection may be implemented in a particularly efficient manner in this way. The bond alloy preferably consists of one of the following mixtures: Au—Si, Al—Ge, Al—Cu—Ge, Cu—Sn, Au—Sn, Au—In, Al—Ge—Si, Al—Cu—Ge—Si, Au—Ge. In principle, all alloy partners which may be used in micromechanics are conceivable. Alloy partners whose phase diagrams provide a eutectic alloy are particularly preferred. Al—Ge is an example of one such alloy. The melting points of the two bond materials are 660° C. for pure aluminum and 938° C. for pure germanium. The melting point at the eutectic point is 420° C. The critical bond temperature required for bonding depends on the mixture and interdiffusion of the materials used during eutectic bonding. In the ideal case, a liquid phase is formed at the melting point at the eutectic point. In the exemplary case of the Al—Ge alloy, the actual bond temperature is usually in the range of 220° C. to 450° C.

Another subject matter of the present invention is a method for manufacturing a micromechanical component. According to the present invention, in a first manufacturing step, on the one hand, the carrier material having the micromechanical structure and, on the other hand, the cap substrate are manufactured, and in a second step the carrier substrate and the cap substrate are joined by connecting the first connecting side and the second connecting side. It is thus advantageously possible to manufacture a more compact micromechanical component in comparison with the related art while nevertheless a secure joint between the carrier substrate and the cap substrate is implementable.

Exemplary embodiments of the present invention are depicted in the drawings and explained in greater detail in the following description.

### BRIEF DESCRIPTION OF THE DRAWINGS

FIG. 1 shows a schematic sectional diagram of a part of a micromechanical component according to the present invention having two stop trenches in the cap substrate.

FIG. 2 shows a schematic top view of the carrier substrate and the cap substrate of a micromechanical component according to the present invention before joining the carrier substrate and the cap substrate.

FIG. 3 shows a schematic sectional diagram of a part of the micromechanical component according to the present invention in which two stop trenches are formed in the edge area of the carrier substrate.

FIG. 4 shows a schematic sectional view of a part of the micromechanical component before connecting the carrier substrate and the cap substrate, with two stop protrusions being situated in the edge area of the cap substrate.

FIG. 5 shows the view according to FIG. 4 but with the carrier substrate and the cap substrate connected.

FIG. 6 shows a schematic sectional diagram of a part of the micromechanical component according to the present invention, two stop trenches and also two stop protrusions being situated in the edge area of the carrier substrate.

FIG. 7 shows a schematic sectional diagram of a part of the micromechanical component according to the present invention, two stop trenches being situated in the cap substrate and two stop protrusions being situated in the cap substrate or in the carrier substrate.

### DETAILED DESCRIPTION

The same parts are always provided with the same reference numerals in the various figures and are each therefore generally cited or mentioned only once.

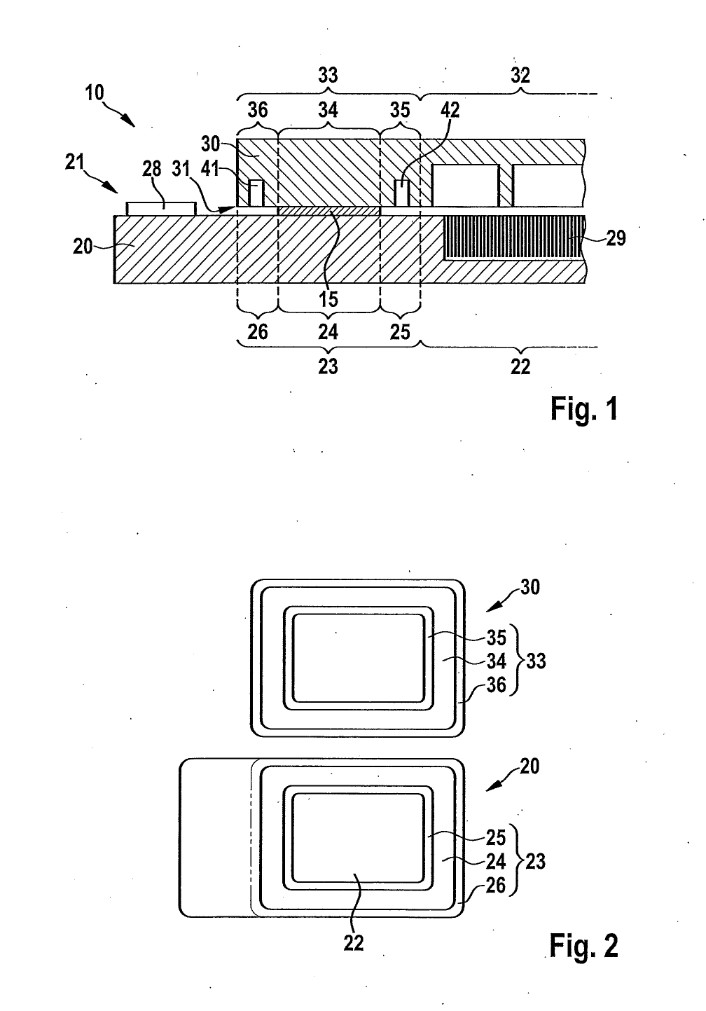

FIGS. 1, 3, 4, 5, 6 and 7 each show a part of a micromechanical component 10 according to the present invention in a schematic sectional diagram, micromechanical component 10 having a carrier substrate 20 and a cap substrate 30. Carrier substrate 20 has a first connecting side 21, and cap substrate 30 has a second connecting side 31, carrier substrate 20 and cap substrate 30 being joined together with their corresponding connecting sides 21 and 31 facing one another, a eutectic bond connection (or a solder connection) being provided in the edge areas of carrier substrate 20 and cap substrate 30 according to the present invention. Carrier substrate 20 has a first structured area 22 and a first edge area 23, first edge area 23 at any rate having a first connecting area 24 and a first bordering area 25 according to the present invention. Cap substrate 30 has a second structured area 32 situated opposite first structured area 22 of carrier substrate 20 in the assembled state of micromechanical component 10. Cap substrate 30 also has a second edge area 33, second edge area 33 having a second connecting area 34 and a second bordering area 35. According to the present invention, first edge area 23 is opposite second edge area 33, and these edge areas at least partially surround respective structured areas 22, 32, but preferably completely, in such a way that with a connection of cap substrate 20 and carrier substrate 30 via edge areas 23, 33 (hereinafter also referred to as the edge area of micromechanical component 10), structured areas 22, 32 are completely surrounded. The connection between carrier substrate 20 and cap substrate 30 via first and second edge areas 23, 33 is implemented via the eutectic bond connection in first and second connecting areas 24, 34 (or via a solder connection), the first and second connecting areas being situated opposite one another. First and second bordering areas 25, 35 are likewise situated opposite one another. If, according to a preferred specific embodiment of the present invention, a third bordering area 26 is also provided in first edge area 23 of carrier substrate 20 (in addition to first bordering area 25) and if a fourth bordering area 36 is also provided in second edge area 33 of cap substrate 30 (in addition to second bordering area 35), which is illustrated in all of FIGS. 1 and 3 through 7, then third bordering area 26 is also opposite fourth bordering area 36.

FIG. 2 schematically shows a top view of carrier substrate 20 and cap substrate 30, the top view onto first connecting side 21 of carrier substrate 20 and onto second connecting side 31 of cap substrate 30 being illustrated, these connecting sides being connected and facing one another in first and second edge areas 23, 33, namely in first and second connecting areas 24, 34 to manufacture micromechanical component 10. FIG. 2 shows that first and second edge areas 23, 33 completely surround first and second structured areas 22, 32. As an alternative to such a specific embodiment, it could also be provided that first and/or second edge areas 23, 33 do not completely surround respective structured areas 22, 32, although this is not shown in FIG. 2.

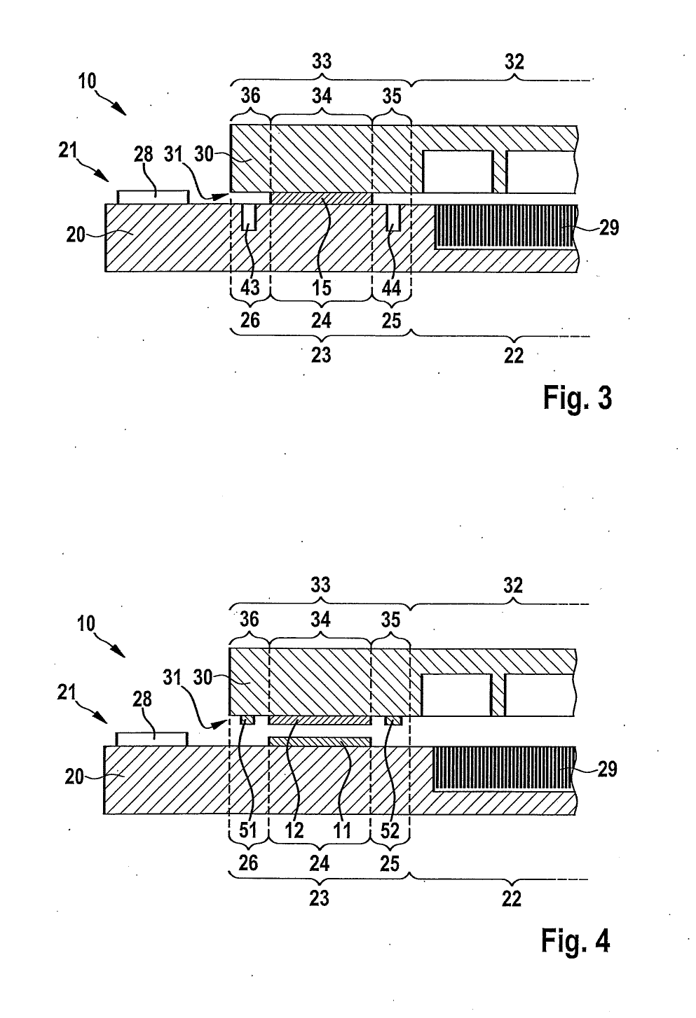

According to a first variant of micromechanical component 10, FIG. 1 shows that a first stop trench 41 is situated in fourth bordering area 36 and a second stop trench 42 is situated in second bordering area 35. According to the embodiment variant in FIG. 3, it is provided that a third stop trench 43 is situated in third bordering area 26 of first edge area 23 of carrier substrate 20 and a fourth stop trench 44 is situated in first bordering area 25 of carrier substrate 20. Since a liquid phase develops during eutectic bonding at temperatures beyond the eutectic point, there is the risk that this phase might run into structured areas 22, 32, in particular due to the compression of carrier substrate 20 and cap substrate 30 to be connected. This may result in sticking of mobile sensor structures, which would cause a failure of micromechanical structure 29. To prevent this, it is provided according to the present invention that at least one stop trench 41, 42, 43, 44 is formed in one of bordering areas 25, 26, 35, 36. In comparison with the design having two stop trenches either in cap substrate 30 according to FIG. 1 or in carrier substrate 20 according to FIG. 3, it could also be possible to provide just one stop trench in each case, in particular in first and second bordering areas 25, 35 or one or two stop trenches in carrier substrate 20 and in cap substrate 30. When carrier substrate 20 and cap substrate 30 are compressed, the gap between these substrates becomes progressively narrower, the eutectic is compressed and the liquid phase is forced laterally out of the connecting area. By providing at least one stop trench, the liquid phase of the eutectic is able to relax into the stop trench. This is facilitated by the fact that it is much more difficult for the eutectic to propagate in a narrow gap as it still exists in the direction of structured areas 22, 32, as viewed from first and second connecting areas 24, 34, beyond second or fourth stop trenches 42, 44 in first or second bordering areas 25, 35. According to the present invention, the area between the stop trench and structured areas 22, 32 is provided with at least one gap which is as narrow as possible between cap substrate 30 and carrier substrate 20, i.e., first and second bordering areas (25, 26) are provided with one or multiple stop trenches according to all variants of micromechanical component 10, so that the narrowest possible gap is formed between cap substrate 30 and sensor carrier substrate 20, between the stop trench and first and second structured areas 23, 33 in the assembled state of micromechanical component 10. According to the present invention, it is possible in this way to protect not only structured areas 22, 32 but also other areas, for example, a bond pad area 28 (in particular via third and fourth bordering areas 26, 36), from the penetrating eutectic. If, according to the present invention, a closed bond frame is used, i.e., edge areas 23, 33 are peripheral, to be able to set a certain pressure in the area of sensor structure 29, for example, it is advantageous if the inner stop trench, i.e., second and fourth stop trenches 42, 44, are provided peripherally around the structured area and along edge area 23, 33 (hereinafter also referred to as bond frame). First and third stop trenches 41, 43 may also be provided completely peripherally according to the present invention, but it is often sufficient to protect only bond pad area 28 from the pinched eutectic in order to be able to ensure problem-free electric contacting of the sensor chip by wire bond. Since in the normal case, stop trenches are manufactured together with the caverns, or micromechanical structures 29 (i.e., together with parts or areas of structured areas 22, 32), they also have almost the same depth as the caverns, or micromechanical structures 29. To increase the stability of the cap substrate with respect to subsequent molding steps, it is advantageous according to the present invention to also design the stop trench depth to be less than that of the caverns, or micromechanical structures 29, by using an additional mask during manufacture of cap substrate 30 or during manufacture of carrier substrate 20.

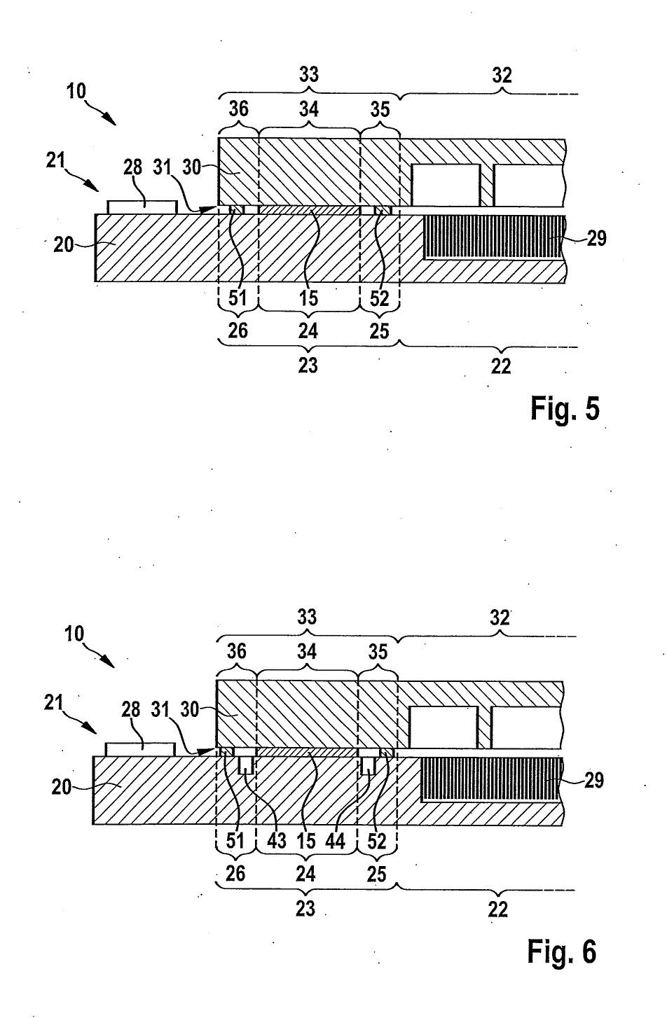

FIG. 4 shows a part of the sectional view of carrier substrate 20 and cap substrate 30 before they are joined to form micromechanical component 10. This shows a first connecting material 11 on the carrier substrate and a second connecting material 12 on cap substrate 30, which together form the eutectic bond connection in connecting areas 24, 34. FIG. 5 shows micromechanical component 10 in the assembled state, i.e., the joined state, of carrier substrate 20 and cap substrate 30. In the embodiment according to FIGS. 4 and 5, a first stop protrusion 51 and a second stop protrusion 52 are provided on cap substrate 30, first stop protrusion 51 being situated in fourth bordering area 36 and second stop protrusion 52 being situated in second bordering area 35. Alternatively, corresponding stop protrusions may also be situated in the first and third bordering areas of the carrier substrate, although that is not illustrated in the drawings. The stop protrusions—as well as the stop trenches—are situated at least partially around the periphery of the contour around structured areas 22, 32 in first and second edge areas 23, 33 (i.e., within the bond frame). Unlike the stop trenches in cap substrate 30 and/or in carrier substrate 20, the stop protrusions have a double function: on the one hand, they should limit pinching of the eutectic to a minimum, and on the other hand, they should limit the lateral flow of the eutectic. The extent to which the liquid phase of the eutectic is pinched depends on how far carrier substrate 20 and cap substrate 30 move toward one another. If stop protrusions are situated vertically (i.e., perpendicular to the main plane of extension of the carrier and cap substrate) on at least one of two carrier and cap substrates 20, 30, in particular in the form of so-called spacers, then the carrier and cap substrates are compressible only to the extent that the stop protrusions come into contact with the opposing wafers (or the respective opposing substrate). It is advantageously possible in this way according to the present invention to achieve a uniform height of the eutectic bond connection over the entire course of the edge area of the micromechanical component around the structured area but also over a greater number of micromechanical components via the joining of two wafers, (i.e., a plurality of individual carrier substrates and a plurality of individual cap substrates) and also to control the quantity of the pinched eutectic. For this purpose, the layer height of the stop protrusion is adapted to the heights of first and second connecting materials 11, 12, (i.e., adapted to the heights of the bond partners). It is true according to the present invention that the height of the stop protrusion should be less than the original height of both bond materials 11, 12, to ensure a contact and a slight pinching of the bond material during the bond process and during the connecting process. If one wants to prevent the eutectic from entering sensor structures, i.e., structured areas 22, 32, then the stop protrusion is preferably designed to be closed completely around structured areas 22, 32. During the bond process, such a stop protrusion running in a ring is pressed onto the surface of the opposing substrate, (i.e., onto the cap substrate, if the stop protrusion is situated on the carrier substrate, and onto the carrier substrate, if the stop protrusion is situated on the cap substrate), thereby sealing the interior. Another stop protrusion may be provided in the outer area of edge areas 23, 33, which either protects only bond pad area 28 against the pinched eutectic or is also provided peripherally around the contour along the edge area.

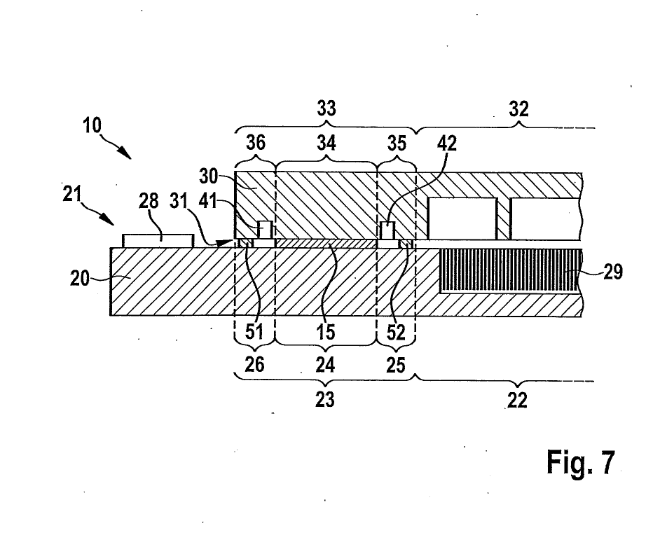

In the implementation of the stop protrusions, according to the present invention the volume defined by the stop protrusion for bond materials 11, 12 and for eutectic bond connection 15 is large enough to be able to receive the pinched eutectic. To ensure that the required volume is definitely present, it is possible and preferred according to the present invention as per the embodiments in FIGS. 6 and 7 that one stop trench (or multiple stop trenches) and one stop protrusion (or multiple stop protrusions) are present in one of the bordering areas or in multiple of the bordering areas. In FIG. 6, for example, first and second stop protrusions 51, 52 are implemented together with third and fourth stop trenches 43, 44 (formed in carrier substrate 20), while in the embodiment according to FIG. 7, first and second stop trenches 41, 42 (in cap substrate 30) are implemented in addition to the implementation of first and second stop protrusions 51, 52.

Materials which are not an integral part of the eutectic, for example, silicon oxide, silicon nitride, silicon or the like are primarily used as materials for the stop protrusions. If the stop structures should be situated at a sufficient distance (in the lateral direction) from connecting materials 11, 12, then the stop protrusions may also be made of the same materials as connecting materials 11, 12.

According to a preferred specific embodiment, it is further conceivable to provide stop trenches and stop protrusions also in the case metallic solder connections or glass solder connections (e.g., glass frit) to be able to define the solder thickness and the usable pinch area here.

What is claimed is:

1. A micromechanical component, comprising:
a carrier substrate including a first connecting side; and
a cap substrate including a second connecting side, wherein:
the carrier substrate and the cap substrate are joined to one another via the first and second connecting sides and via one of a eutectic bond connection, a metallic solder connection, and a glass solder connection,
the first connecting side includes a first structured area that includes a micromechanical structure and a first edge area,
the first edge area at least partially surrounds the first structured area on the first connecting side,
the second connecting side includes a second structured area opposite the first structured area and a second edge area,
the second edge area at least partially surrounds the second structured area on the second connecting side,
the first edge area includes a first connecting area and a first bordering area,
the second edge area includes a second connecting area and a second bordering area,
the first and second connecting areas are situated opposite one another,
the first and second bordering areas are situated opposite one another, and
one of the first bordering area and the second bordering area includes one of:
one of a stop trench and a stop protrusion, and
both the stop trench and the stop protrusion.

2. The micromechanical component as recited in claim 1, wherein:
the first bordering area is situated between the first connecting area and the first structured area, and
the second bordering area is situated between the second connecting area and the second structured area.

3. The micromechanical component as recited in claim 1, wherein:
the first edge area includes a third bordering area next to the first bordering area,
the second edge area includes a fourth bordering area next to the second bordering area,
the first connecting area is situated between the first and third bordering areas, and
the second connecting area is situated between the second and fourth bordering areas.

4. The micromechanical component as recited in claim 1, wherein:
the first edge area completely surrounds the first structured area on the first connecting side, and
the second edge area completely surrounds the second structured area on the second connecting side.

5. The micromechanical component as recited in claim 1, wherein:
the eutectic bond connection comes about through a first bond partner and a second bond partner,
the first bond partner is provided in the first connecting area, and
the second bond partner is provided in the second connecting area.

6. The micromechanical component as recited in claim 1, further comprising at least one of:
a stop protrusion situated in the first edge area and coming into contact with the second edge area; and
a stop protrusion situated in the second edge area and coming into contact with the first edge area.

7. The micromechanical component as recited in claim 1, wherein:
the micromechanical structure is one of a sensor structure and an actuator structure.

8. The micromechanical component as recited in claim 1, wherein:
the micromechanical structure includes a sensor structure for at least one of an acceleration measurement and a yaw rate measurement.

9. The micromechanical component as recited in claim 1, wherein:
a predetermined gas atmosphere prevails between the first structured area of the carrier substrate and the second structured area of the cap substrate.

10. The micromechanical component as recited in claim 9, wherein:
the predetermined gas atmosphere includes a predetermined internal pressure.

11. The micromechanical component as recited in claim 1, wherein the micromechanical component is a micromechanical sensor.

12. A method for manufacturing a micromechanical component that includes:
a carrier substrate including a first connecting side; and
a cap substrate including a second connecting side, wherein:
the carrier substrate and the cap substrate are joined to one another via the first and second connecting sides and via one of a eutectic bond connection, a metallic solder connection, and a glass solder connection,
the first connecting side includes a first structured area that includes a micromechanical structure and a first edge area,
the first edge area at least partially surrounds the first structured area on the first connecting side,
the second connecting side includes a second structured area opposite the first structured area and a second edge area,
the second edge area at least partially surrounds the second structured area on the second connecting side,
the first edge area includes a first connecting area and a first bordering area,
the second edge area includes a second connecting area and a second bordering area,
the first and second connecting areas are situated opposite one another,
the first and second bordering areas are situated opposite one another, and
one of the first bordering area and the second bordering area includes one of:
one of a stop trench and a stop protrusion, and
both the stop trench and the stop protrusion, the method comprising:
manufacturing the carrier substrate and the cap substrate; and
joining together the carrier substrate and the cap substrate by joining the first connecting side and the second connecting side.
